(19) United States
(12) Patent Application Publication
(10) Pub. No.: US 2025/0133868 A1
(43) Pub. Date: Apr. 24, 2025

(54) MANUFACTURING METHOD OF ELECTRONIC DEVICE

(71) Applicant: Innolux Corporation, Miaoli County (TW)

(72) Inventors: Yu-Jhou Gong, Miaoli County (TW); Tsung-Han Tsai, Miaoli County (TW); Kuan-Feng Lee, Miaoli County (TW); Te-Yu Lee, Miaoli County (TW); Hsin Chiang, Miaoli County (TW)

(73) Assignee: Innolux Corporation, Miaoli County (TW)

(21) Appl. No.: 18/896,767

(22) Filed: Sep. 25, 2024

Related U.S. Application Data
(60) Provisional application No. 63/592,538, filed on Oct. 23, 2023.

(30) Foreign Application Priority Data
Jun. 20, 2024 (CN) 202410803277.1

(51) Int. Cl. H01L 33/00; H01L 21/66

(52) U.S. Cl. CPC H10H 20/018; H01L 22/12

(57) ABSTRACT

A method of manufacturing an electronic device includes: forming a sacrificial layer on a substrate; forming a semiconductor structure on the sacrificial layer; separating the semiconductor structure from the substrate; detecting defects on the substrate; and classifying the substrate.

### CROSS-REFERENCE TO RELATED APPLICATION

This application claims the priority benefit of U.S. provisional application Ser. No. 63/592,538, filed on Oct. 23, 2023, and China application no. 202410803277.1, filed on Jun. 20, 2024. The entirety of each of the above-mentioned patent applications is hereby incorporated by reference herein and made a part of this specification.

### BACKGROUND

### Field of the Disclosure

The present disclosure relates to a manufacturing method of an electronic device.

### Description of Related Art

The manufacturing cost of existing electronic devices (such as electronic devices including light-emitting diodes) is high. In light of the foregoing, how to reduce the manufacturing cost of electronic devices is now one of the problems that practitioners need to solve urgently.

### SUMMARY OF THE DISCLOSURE

The present disclosure provides a manufacturing method of an electronic device, which helps to reduce manufacturing costs.

In embodiment of the present disclosure, a method of manufacturing an electronic device includes: forming a sacrificial layer on a substrate; forming a semiconductor structure on the sacrificial layer; separating the semiconductor structure from the substrate; detecting defects on the substrate; and classifying the substrate.

In another embodiment of the present disclosure, a manufacturing method of an electronic device includes: forming a semiconductor structure on a recycled substrate; separating the semiconductor structure from the recycled substrate; performing product inspection on the semiconductor structure; and performing recycling inspection on the recycled substrate.

In order to make the above-mentioned features and advantages of the present disclosure more clear and easy to understand, embodiments are given below and are described in detail below with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A and FIG. 1B are block diagrams of a manufacturing method of an electronic device according to some embodiments of the present disclosure.

FIG. 2, FIG. 3, FIG. 4, and FIG. 5 are schematic cross-sectional views respectively illustrating four examples of forming a sacrificial layer on a substrate.

FIG. 6, FIG. 7, and FIG. 8 are schematic cross-sectional diagrams respectively illustrating three examples of forming semiconductor structures on the sacrificial layer.

FIG. 9, FIG. 10, FIG. 11, FIG. 12, FIG. 13, FIG. 14, FIG. 15, and FIG. 19 are schematic diagrams respectively showing eight examples of separating a semiconductor structure from a substrate.

FIG. 16A to FIG. 16C are schematic cross-sectional diagrams illustrating the laser cutting process.

FIG. 17 is a schematic cross-sectional diagram illustrating laser cutting using alignment patterns.

FIG. 18 is a schematic cross-sectional diagram illustrating laser cutting using a ruler.

FIG. 20 is a schematic diagram illustrating removal of the sacrificial layer or impurities remaining on the substrate.

FIG. 21 is a schematic diagram illustrating the detection of defects and cracks on the substrate.

FIG. 22 is a schematic cross-sectional diagram illustrating the reduction of the size of the substrate in the presence of defects.

FIG. 23 is a schematic cross-sectional diagram illustrating the reduction of the size of the substrate in the presence of cracks.

FIG. 24 is a schematic diagram illustrating performing chemical-mechanical polishing (CMP) on the substrate.

FIG. 25 is a schematic diagram illustrating detecting the thickness of the substrate.

FIG. 26 is a schematic diagram illustrating detecting the surface roughness of the substrate.

FIG. 27 is a schematic diagram illustrating performing wet chemical cleaning on the substrate.

FIG. 28 is a schematic diagram illustrating classifying the substrate according to thickness of the substrate.

FIG. 29A and FIG. 29B are block diagrams of a manufacturing method of an electronic device according to other embodiments of the present disclosure.

FIG. 30 is a schematic diagram illustrating performing CMP on a buffer layer.

FIG. 31 is a schematic diagram illustrating detecting the thickness of the buffer layer on the substrate.

FIG. 32 is a schematic diagram illustrating detecting the surface roughness of the buffer layer on the substrate.

FIG. 33 is a schematic diagram illustrating classifying the substrate according to the thickness of the substrate and the surface roughness of the buffer layer on the substrate.

FIG. 34 is a block diagram of a manufacturing method of an electronic device according to some other embodiments of the present disclosure.

### DESCRIPTION OF EMBODIMENTS

Reference will now be made in detail to the exemplary embodiments of the present disclosure, examples of which are illustrated in the accompanying drawings. Whenever possible, the same reference numbers are used in the drawings and descriptions to refer to the same or similar parts.

In the description of the disclosure and the appended claims, certain terms will be used to refer to specific elements. Persons skilled in the art would understand that electronic device manufacturers may refer to the same elements under different names. This disclosure does not intend to distinguish between elements that have the same functions but different names. In the following description and appended claims, the words “have” and “include” are open-ended words, so they should be interpreted to mean “including but not limited to . . . ”.

Directional terminology mentioned in the specification, such as “top”, “bottom”, “front”, “back”, “left”, “right”, etc., is used with reference to the orientation of the figures being described. Therefore, the used directional terminology is only illustrative, and is not intended to be limiting of the disclosure. In the figures, the drawings illustrate general characteristics of methods, structures, and/or materials used in specific embodiments. However, these drawings should not be construed as defining or limiting of a scope or nature covered by these embodiments. For example, for clarity's sake, a relative size, a thickness and a location of each film layer, area and/or structure may be reduced or enlarged.

It should be understood that, relative terms, such as “lower” or “bottom” or “higher” or “top,” may be used in the embodiments to describe the relative relationship of one element of the drawings to another element. It will be understood that if the device in the figures were turned upside down, elements described on the “lower” side would become elements described on the “higher” side. The embodiments of the disclosure may be understood together with the drawings, and the drawings of the disclosure are also regarded as a part of the disclosure description.

One structure (or layer, element, substrate) described in the disclosure is located on/above another structure (or layer, element, substrate), which means that the two structures are adjacent and in direct connection, or means that the two structures are adjacent but in indirect connection. Indirect connection means that there is at least one intermediate structure (or intermediate layer, intermediate element, intermediate substrate, intermediate space) between the two structures, a lower surface of a structure is adjacent or directly connected to an upper surface of the intermediate structure, and an upper surface of the other structure is adjacent to or directly connected to a lower surface of the intermediate structure. The intermediary structure may be composed of a single-layer or multi-layer physical structure or non-physical structure, which is not limited by the disclosure. In the disclosure, when a certain structure is described to be “on” another structure, it means that the certain structure is “directly” on the another structure, or means that the certain structure is “indirectly” on the another structure, i.e., at least one structure is further clamped between the certain structure and the another structure.

The terms “about”, “substantially” or “approximately” are generally interpreted as being within 10% of a given value or range, or interpreted as being within 5%, 3%, 2%, 1%, or 0.5% of the given value or range. In addition, the wordings “the range is from the first numerical value to the second numerical value” and “the range falls between the first numerical value and the second numerical value” mean that the range includes the first numerical value, the second numerical value, and other numerical values therebetween.

The ordinal numbers used in the specification and claims, such as “first”, “second”, etc., are used to modify components, and do not imply and represent that the component or these components have any previous ordinal numbers, and do not represent a sequence of one component with another, or a sequence in a manufacturing method. The use of these ordinal numbers is only to make a clear distinction between one component with a certain name and another component with the same name. The same terms may not be used in the claims and the specification, and accordingly, a first component in the specification may be a second component in the claims.

The electrical connection or coupling described in this disclosure may refer to direct connection or indirect connection. In the case of direct connection, terminals of components on two circuits are directly connected or connected to each other by a conductor line segment, and in the case of indirect connection, there are switches, diodes, capacitors, inductors, resistors, other suitable components, or a combination of the above components between the terminals of the components on the two circuits, but the disclosure is not limited thereto.

In the disclosure, the thickness, length and width may be measured by an optical microscope (OM), and the thickness or width may be obtained by measuring a cross-sectional image in the electron microscope, but the disclosure is not limited thereto. In addition, a certain error may be provided between any two values or directions used for comparison. Moreover, the expressions “the given range is a first value to a second value”, “the given range falls within a range of the first value to the second value” or “the given range is between the first value and the second value” mean that the given range includes the first value, the second value, and other values there between. If a first direction is perpendicular to a second direction, an angle between the first direction and the second direction may be between 80 degrees and 100 degrees; and if the first direction is parallel to the second direction, the angle between the first direction and the second direction may be between 0 degree and 10 degrees.

Unless otherwise defined, all terms (including technical and scientific terms) used herein have the same meanings as commonly understood by those skilled in the art to which this disclosure belongs. It is understandable that these terms, such as those defined in commonly used dictionaries, should be interpreted as having meaning consistent with the relevant technology and the background or context of this disclosure, and should not be interpreted in an idealized or excessively formal way, unless there is a special definition in the embodiment of the disclosure.

In the disclosure, the electronic device may include a power device, a semiconductor packaging device, a display device, a backlight device, an antenna device, a packaging device, a sensing device, or a splicing device, but the disclosure is not limited thereto. The electronic device may be a bendable or flexible electronic device. The display device may be a non-self-luminous type display device or a self-luminous type display device. The display device may include, for example, liquid crystal, light-emitting diode, fluorescence, phosphor, quantum dot (QD), other suitable display media, or a combination of the foregoing. The antenna device may, for example, include a reconfigurable intelligent surface (RIS), a frequency selective surface (FSS), a radio frequency filter (RF-Filter), a polarizer, a resonator or an antenna, etc. The antenna may be a liquid crystal antenna or a varactor diode antenna. The sensing device may be a sensing device that senses capacitance, light, heat, or ultrasound, but the disclosure is not limited thereto. In the disclosure, the electronic device may include electronic components, and the electronic components may include passive components and active components, such as known good die (KGD), capacitors, resistors, inductors, diodes, transistors, varactor diodes, variable capacitors, filters, noise cancellers, sensors, microelectromechanical system components (MEMS), liquid crystal chips, biosensing chips, semiconductor-related processes structures, or the structure of a semiconductor-related process disposed on a substrate (such as polyimide, glass, silicon substrate, circuit board or other suitable substrate materials), but the disclosure is not limited thereto. The diode may include a light-emitting diode, a varactor diode or a photodiode. The light-emitting diode may include, for example, an organic light-emitting diode (OLED), a mini LED, a micro LED, a sub-micro LED, a nano-rod LED or a quantum dot LED, but the disclosure is not limited thereto. The splicing device may be, for example, a display splicing device or an antenna splicing device, but the disclosure is not limited thereto. It should be noted that the electronic device may be any arrangement and combination of the foregoing, but the disclosure is not limited thereto. The packaging device may be suitable for a wafer-level packaging (WLP) technique or a panel-level packaging (WLP) technique, such as a packaging device of a chip-first process or an RDL-first process. In addition, the shape of the electronic device may be rectangular, circular, polygonal, a shape having curved edges, or other suitable shapes. The electronic device may have a peripheral system such as a driving system, a control system, a light source system, etc. to support a display device, an antenna device, a wearable device (for example, including augmented reality or virtual reality), a vehicle-mounted device (for example, including car windshields) or a splicing device. The following embodiments use packaging devices as examples to illustrate some implementation types of electronic devices, but are not limited thereto. According to embodiments of the present disclosure, the manufacturing method of the electronic device provided may be applied, for example, to a wafer-level package (WLP) or panel-level package (PLP) process, and may adopt a chip first process or a chip last/RDL first process, which will be explained in further detail below. According to embodiments of the present disclosure, the packaging structure of the electronic device may include a system on chip (SoC), a system in package (SiP), an antenna in package (AiP), or a combination thereof, but not the disclosure is not limited thereto.

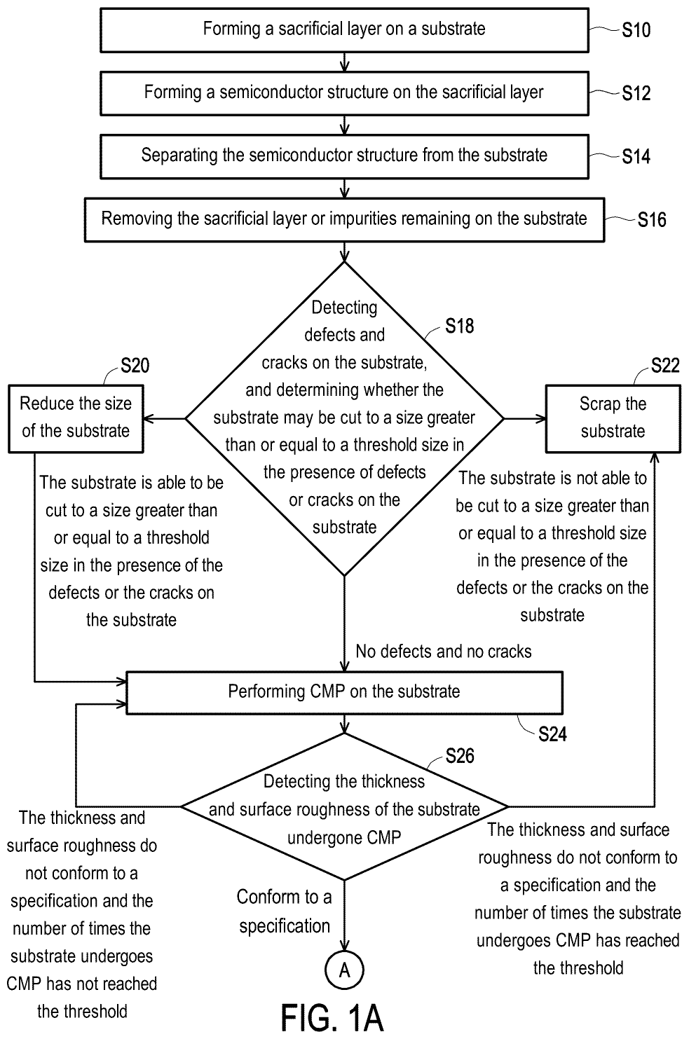

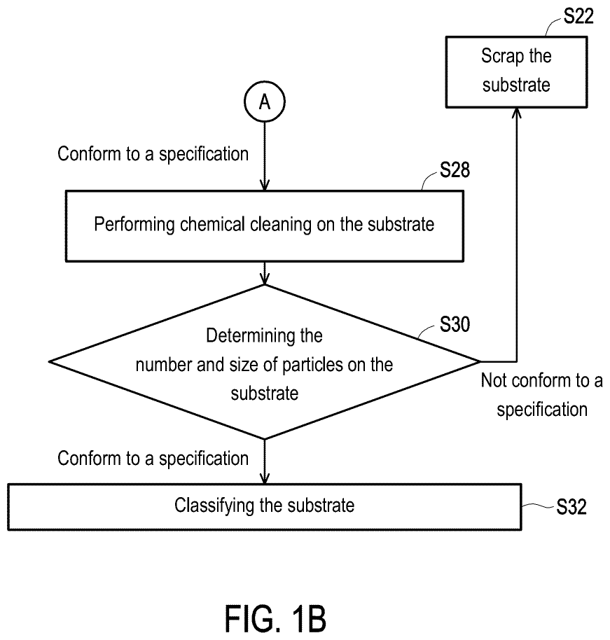

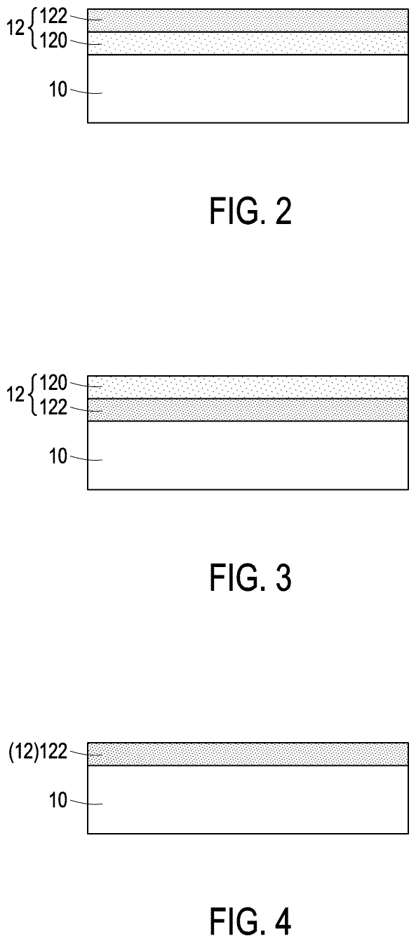

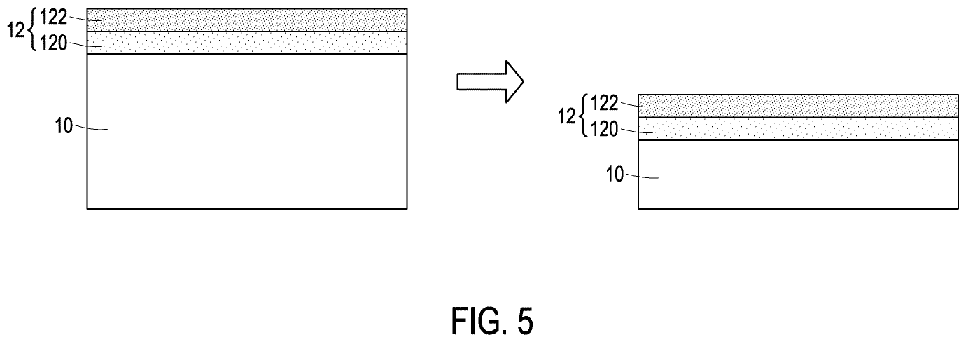

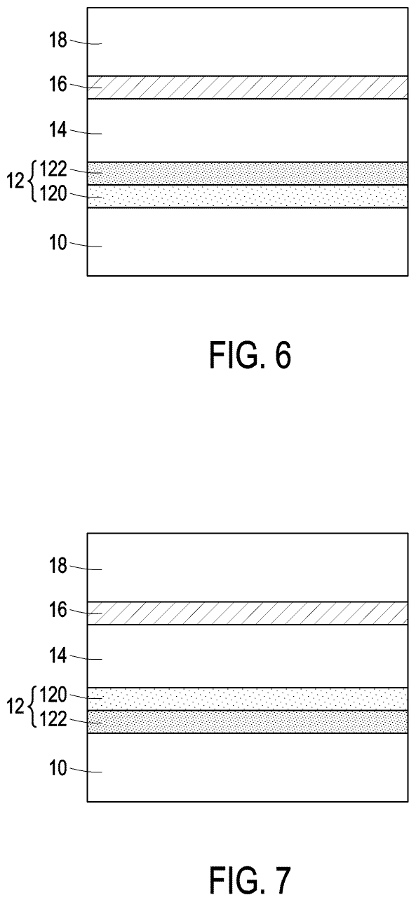

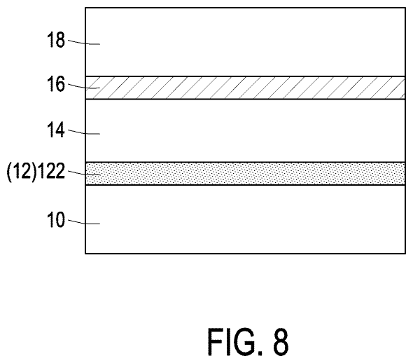

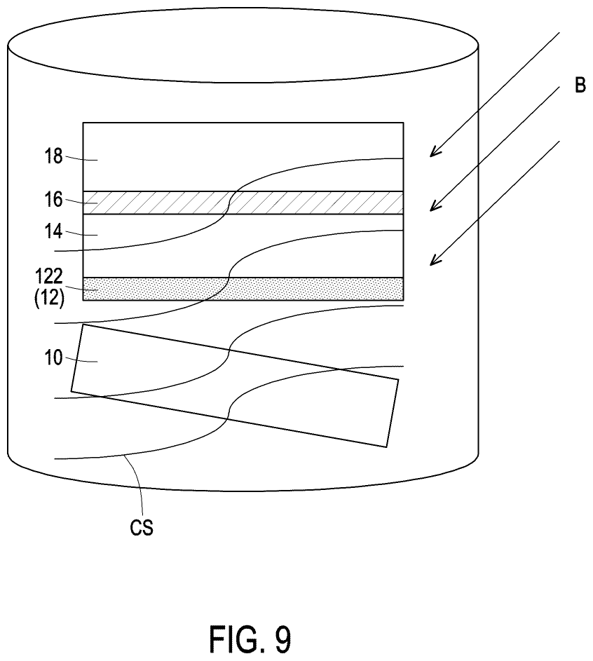

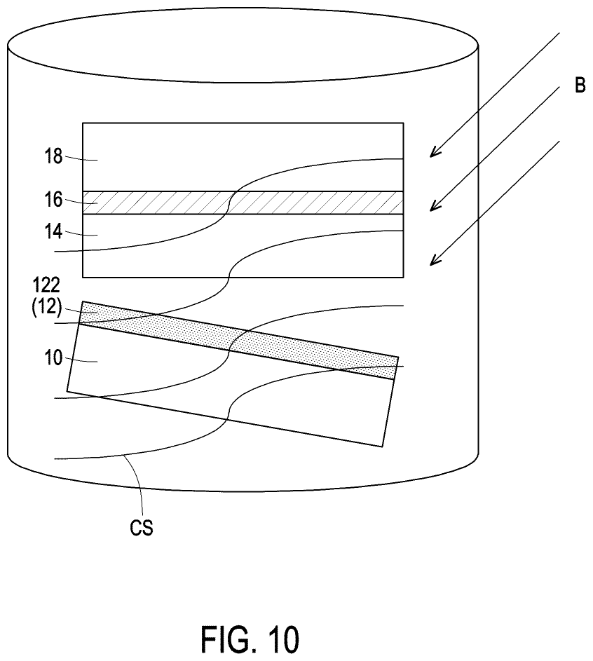

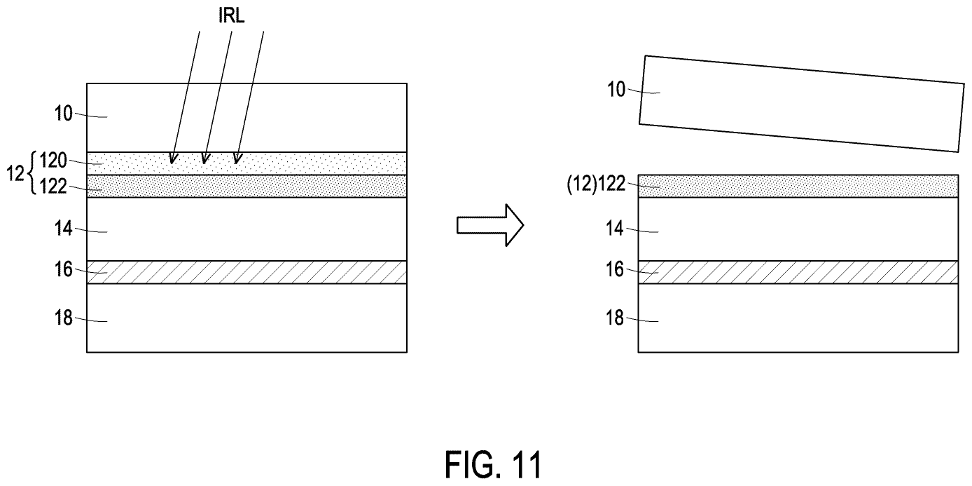

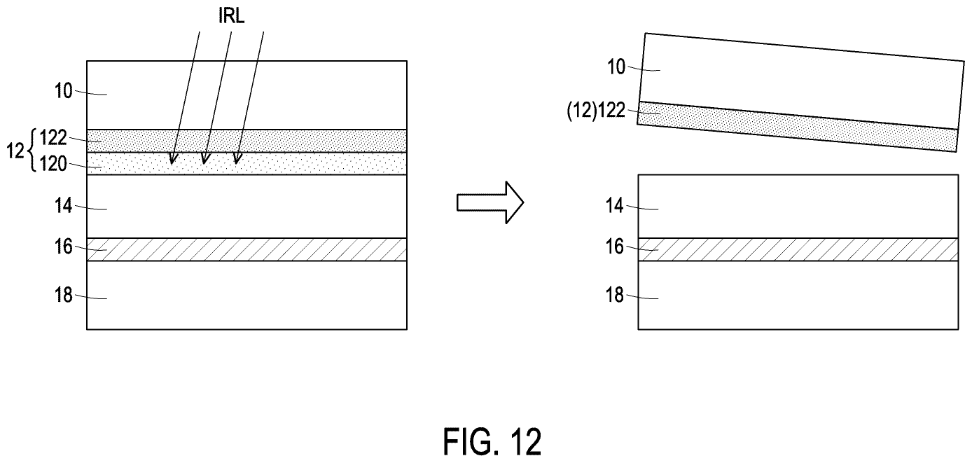

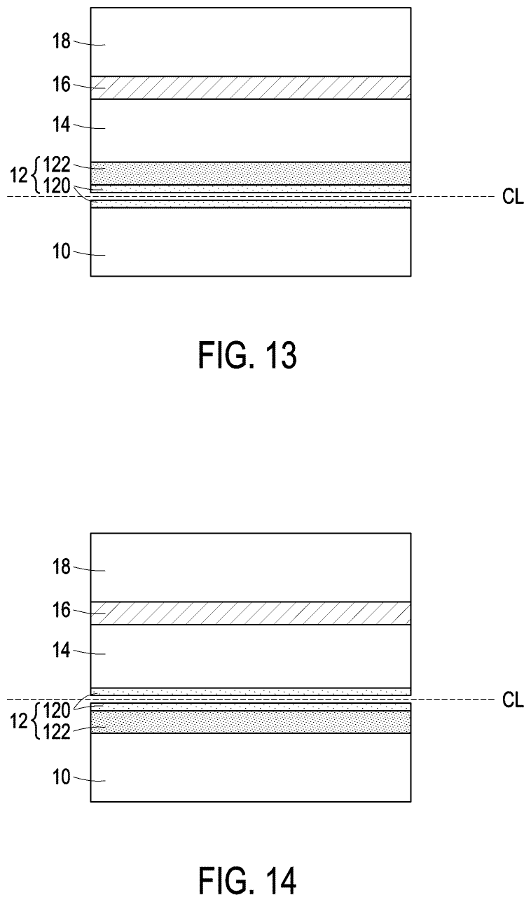

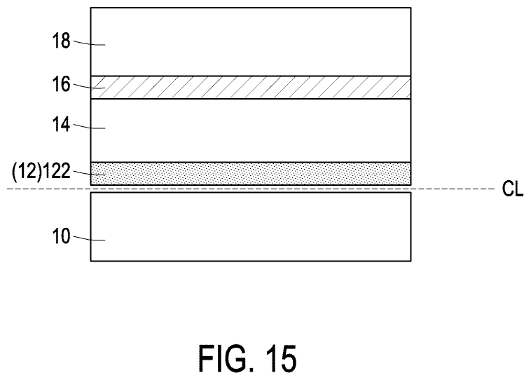

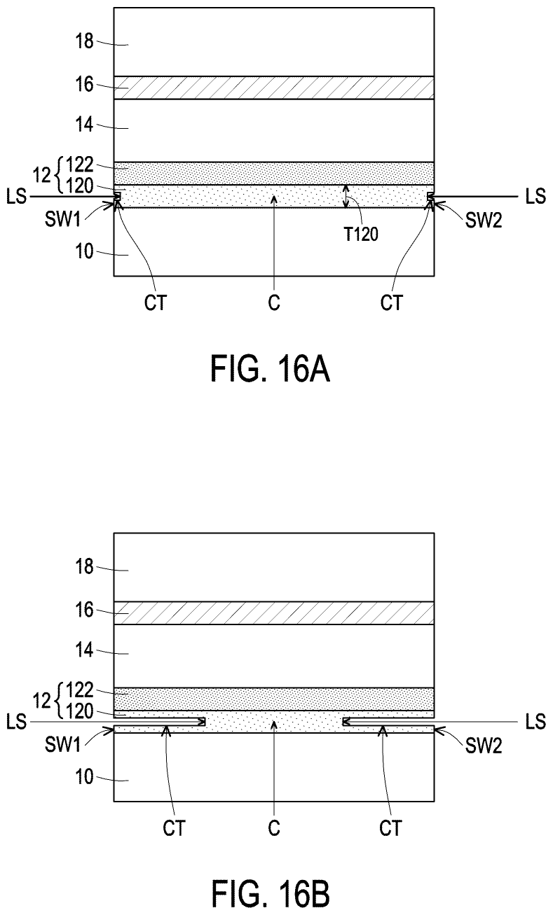

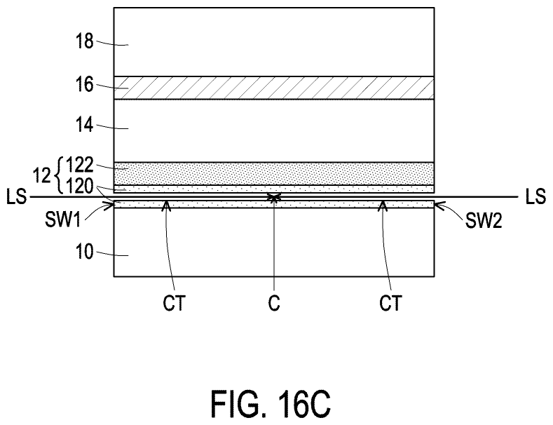

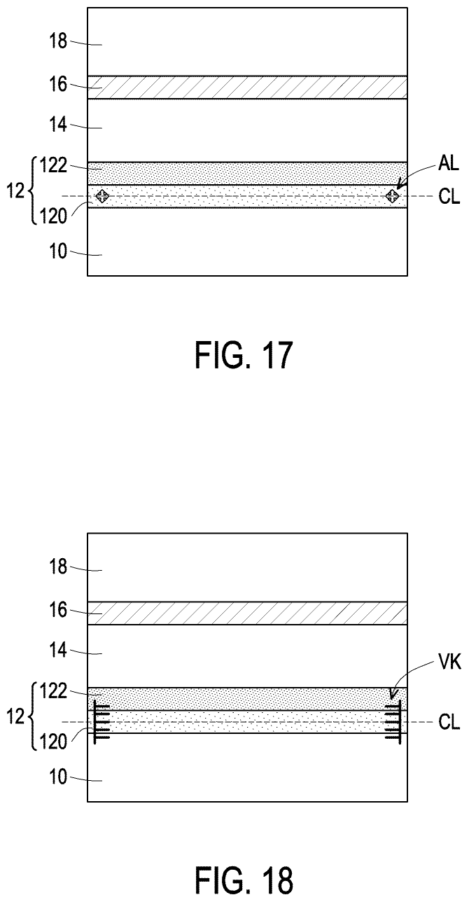

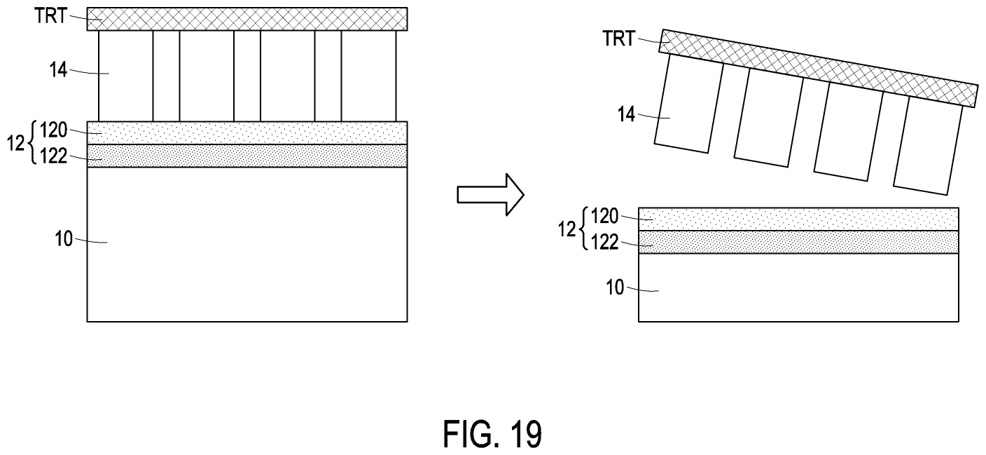

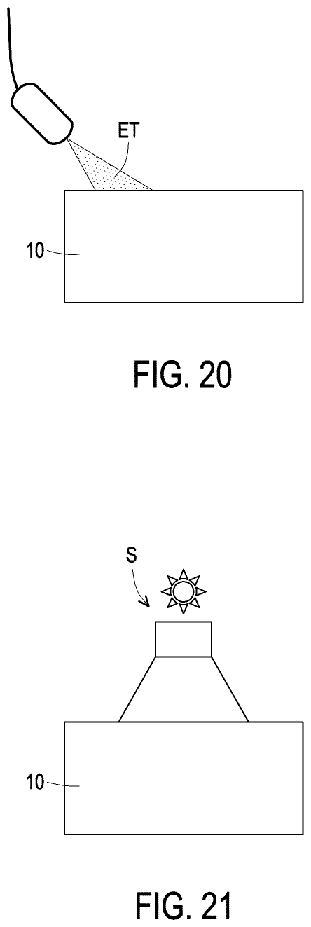

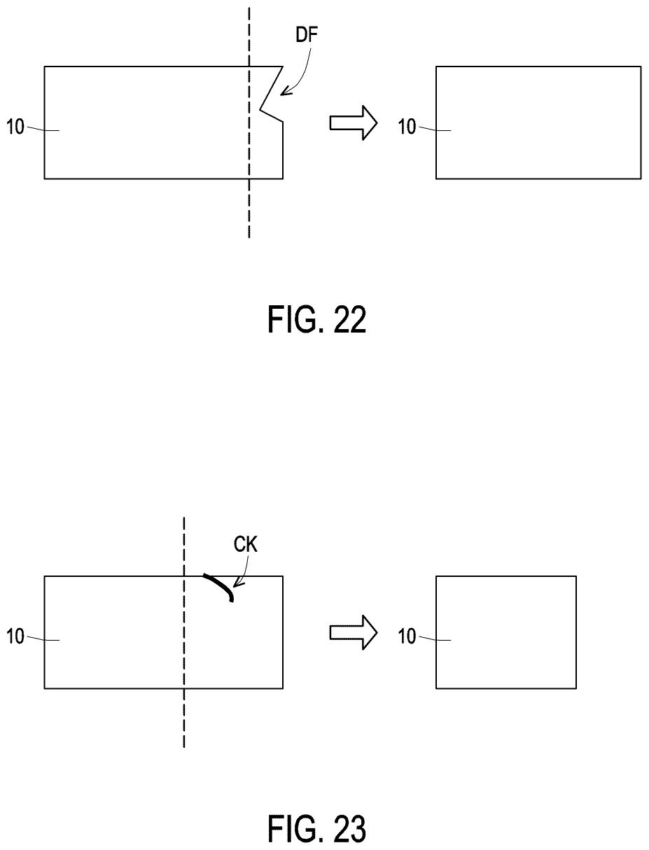

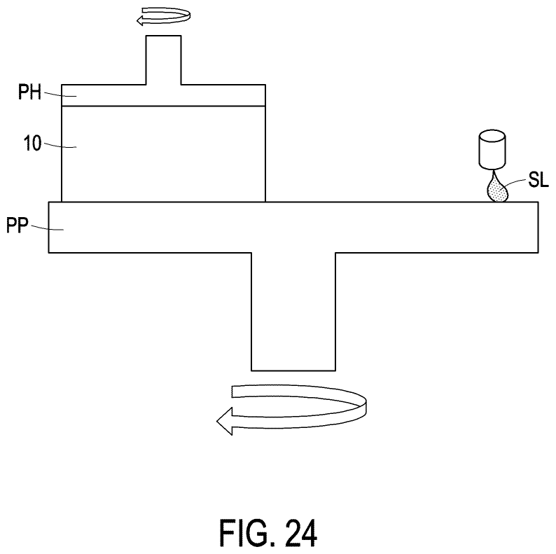

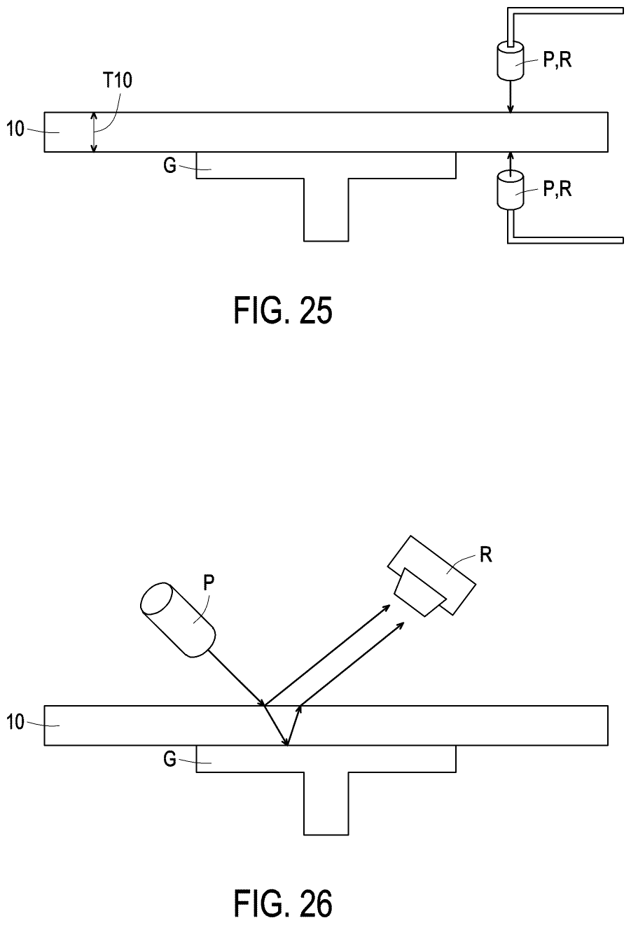

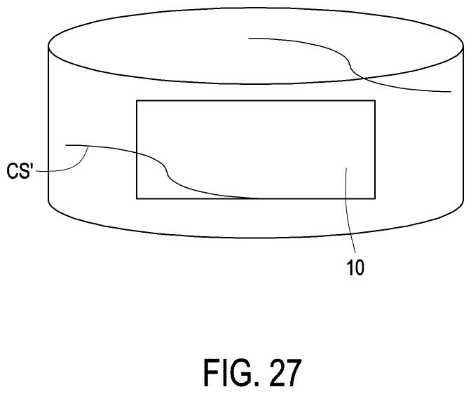

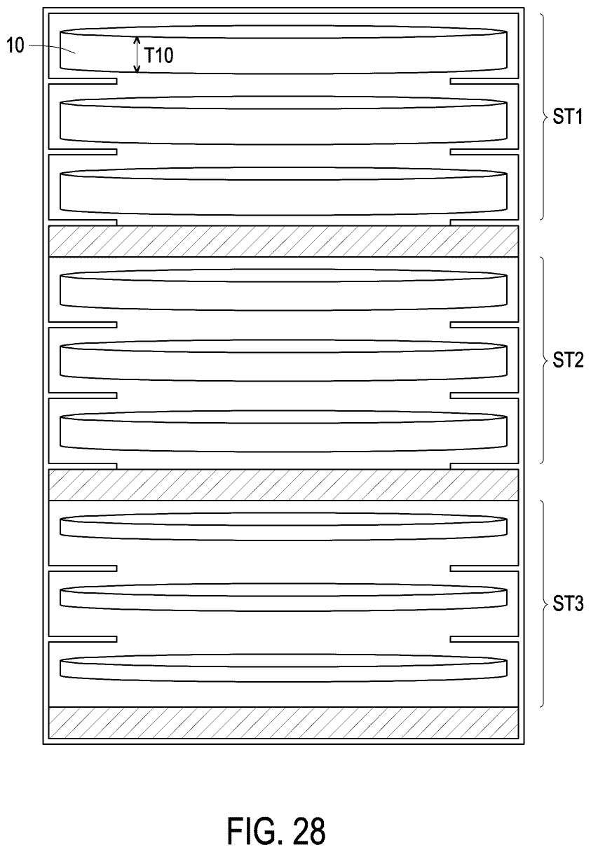

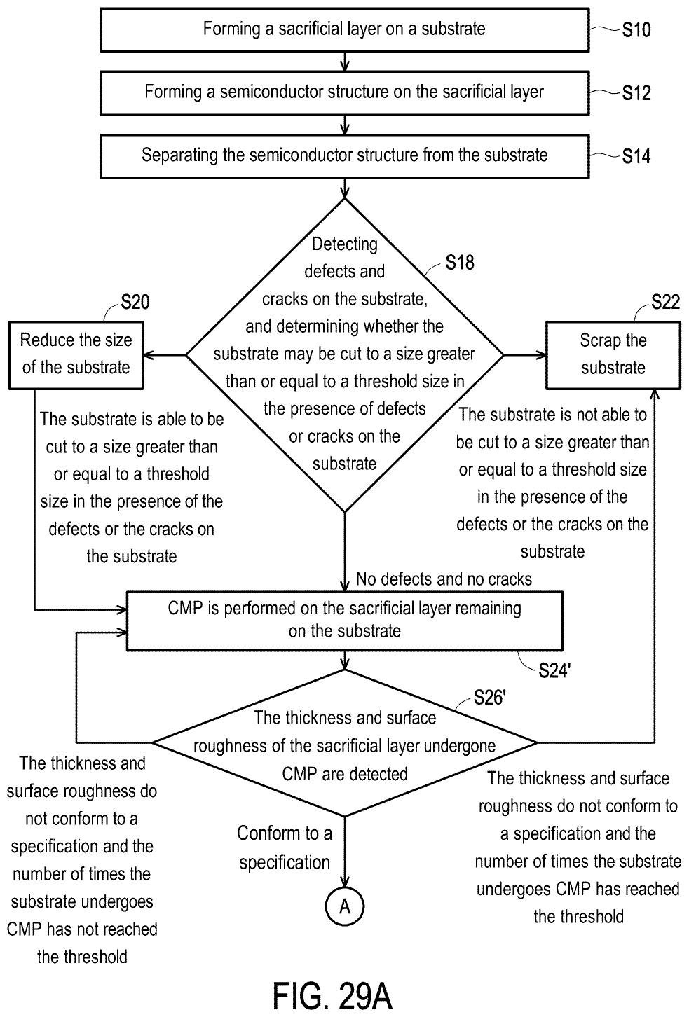

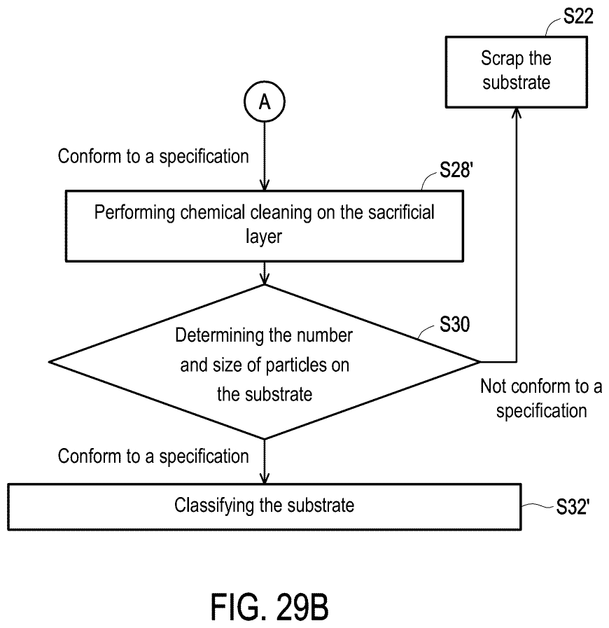

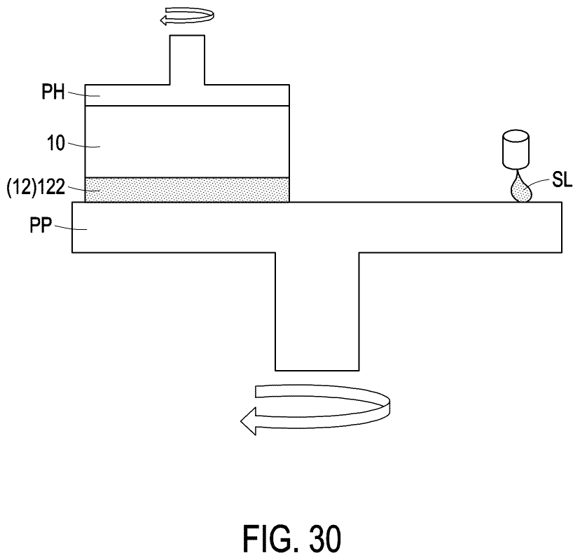

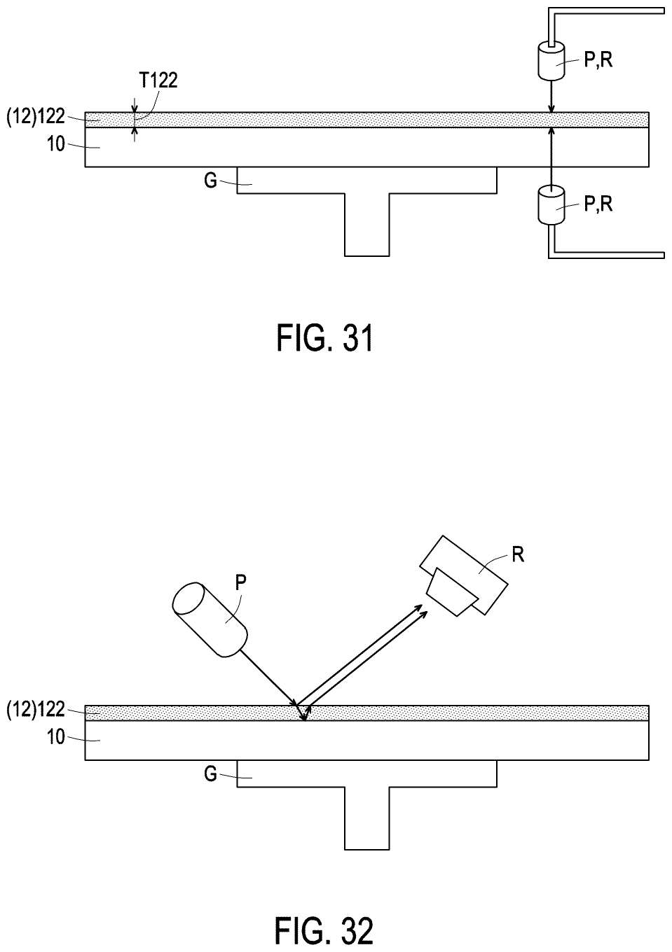

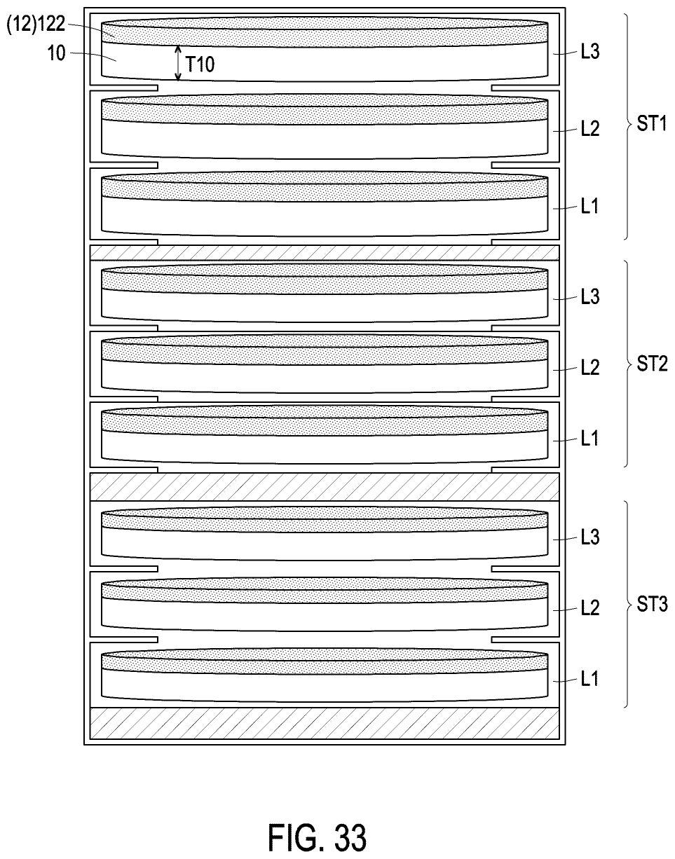

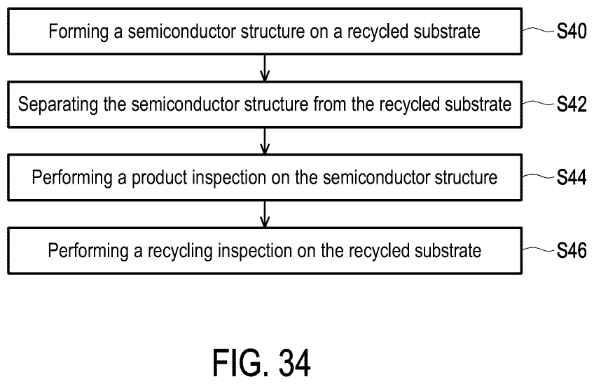

FIG. 1A and FIG. 1B are block diagrams of a manufacturing method of an electronic device according to some embodiments of the present disclosure. FIG. 2, FIG. 3, FIG. 4, and FIG. 5 are schematic cross-sectional views respectively illustrating four examples of forming a sacrificial layer on a substrate. FIG. 6, FIG. 7, and FIG. 8 are schematic cross-sectional diagrams respectively illustrating three examples of forming semiconductor structures on the sacrificial layer. FIG. 9, FIG. 10, FIG. 11, FIG. 12, FIG. 13, FIG. 14, FIG. 15, and FIG. 19 are schematic diagrams respectively showing eight examples of separating a semiconductor structure from a substrate. FIG. 16A to FIG. 16C are schematic cross-sectional diagrams illustrating the laser cutting process. FIG. 17 is a schematic cross-sectional diagram illustrating laser cutting using alignment patterns. FIG. 18 is a schematic cross-sectional diagram illustrating laser cutting using a ruler. FIG. 20 is a schematic diagram illustrating removal of the sacrificial layer or impurities remaining on the substrate. FIG. 21 is a schematic diagram illustrating the detection of defects and cracks on the substrate. FIG. 22 is a schematic cross-sectional diagram illustrating the reduction of the size of the substrate in the presence of defects. FIG. 23 is a schematic cross-sectional diagram illustrating the reduction of the size of the substrate in the presence of cracks. FIG. 24 is a schematic diagram illustrating performing chemical-mechanical polishing (CMP) on the substrate. FIG. 25 is a schematic diagram illustrating detecting the thickness of the substrate. FIG. 26 is a schematic diagram illustrating detecting the surface roughness of the substrate. FIG. 27 is a schematic diagram illustrating performing wet chemical cleaning on the substrate. FIG. 28 is a schematic diagram illustrating classifying the substrate according to thickness of the substrate. FIG. 29A and FIG. 29B are block diagrams of a manufacturing method of an electronic device according to other embodiments of the present disclosure. FIG. 30 is a schematic diagram illustrating performing CMP on a buffer layer. FIG. 31 is a schematic diagram illustrating detecting the thickness of the buffer layer on the substrate. FIG. 32 is a schematic diagram illustrating detecting the surface roughness of the buffer layer on the substrate. FIG. 33 is a schematic diagram illustrating classifying the substrate according to the thickness of the substrate and the surface roughness of the buffer layer on the substrate. FIG. 34 is a block diagram of a manufacturing method of an electronic device according to some other embodiments of the present disclosure. It should be noted that technical features in different embodiments described below may be replaced, reorganized, or mixed with each other to achieve other embodiments without departing from the spirit of the disclosure. Features in various embodiments may be mixed and matched as long as they do not violate the spirit of the disclosure or conflict with each other.

According to some embodiments of the present disclosure, the manufacturing method of the electronic device may include: forming a sacrificial layer 12 on a substrate 10 (refer to step S10 of FIG. 1A; FIG. 2 to FIG. 4); forming a semiconductor structure 14 on the sacrificial layer 12 (refer to step S12 of FIG. 1A; FIG. 6 to FIG. 8); separating the semiconductor structure 14 from the substrate 10 (refer to step S14 of FIG. 1A; FIG. 9 to FIG. 19); detecting defects on the substrate 10 (refer to step S18 in FIG. 1A; FIG. 21); and classifying the substrate 10 (refer to step S32 of FIG. 1B; FIG. 28 or FIG. 32), but the disclosure is not limited thereto. According to different requirements, the manufacturing method of the electronic device may optionally include other steps, such as the steps shown in FIG. 1A and FIG. 1B, but is not limited thereto. In other embodiments, the manufacturing method of the electronic device may omit one or more steps shown in FIG. 1A and FIG. 1B or may add one or more steps not shown.

Specifically, as shown in step S10 of FIG. 1A, the manufacturing method of the electronic device may include forming the sacrificial layer 12 on the substrate 10. The substrate 10 may be configured to support film layers formed thereon. In some embodiments, the substrate 10 may be a silicon substrate, such as a silicon (111) substrate, but the disclosure is not limited thereto. Compared with using a sapphire substrate, using a silicon substrate as a growth substrate for the semiconductor structure 14 may help reduce process costs, but the present disclosure is not limited thereto. In other embodiments, the substrate 10 may be a sapphire substrate or other types of substrates, and the process cost may be reduced by recycling the substrates.

The sacrificial layer 12 may be configured to relieve stress caused by lattice constant mismatch and/or thermal expansion coefficient mismatch, block defects, improve mechanical strength, improve adhesion, and/or assist in the separation of the semiconductor structure 14 from the substrate 10. In some embodiments, as shown in FIG. 2 to FIG. 5, the sacrificial layer 12 may include a buffer layer 122, a peeling layer 120, or a combination thereof. Taking FIG. 2, FIG. 4 or FIG. 5 as an example, the sacrificial layer 12 may include a peeling layer 120 and a buffer layer 122. The material of the peeling layer 120 includes, for example, aluminum gallium nitride, graphene, a combination of graphene and aluminum oxide, indium gallium nitride, aluminum indium gallium nitride, aluminum indium gallium arsenide, silicon carbide, other suitable organic materials, or other suitable inorganic materials or other suitable metal oxides. The material of the buffer layer 122 includes, for example, N-type gallium nitride, graphene, aluminum nitride, silicon dioxide, aluminum oxide, other suitable organic materials or other suitable inorganic materials. On the other hand, as shown in FIG. 4, the sacrificial layer 12 may include the buffer layer 122 and not include the peeling layer 120. Alternatively, although not shown, the sacrificial layer 12 may include the peeling layer 120 and not the buffer layer 122.

In some embodiments, as shown in FIG. 2 or FIG. 5, the peeling layer 120 and the buffer layer 122 may be formed on the substrate 10 sequentially. In other embodiments, as shown in FIG. 3, the buffer layer 122 and the peeling layer 120 may be formed sequentially on the substrate 10. Alternatively, as shown in FIG. 5, the substrate 10 may be a silicon substrate, and the manufacturing method of the electronic device may further include: after forming the sacrificial layer 12 on the silicon substrate, cutting the silicon substrate into thin substrates. The method of cutting the silicon substrate may include wire cutting, but the disclosure is not limited thereto. Under the architecture of FIG. 5, it is not limited that the sacrificial layer 12 is formed on the peeling layer 120 and the buffer layer 122 sequentially on the substrate 10. Alternatively, the positions of the peeling layer 120 and the buffer layer 122 in FIG. 5 may be interchanged, or one of the peeling layer 120 and the buffer layer 122 may be omitted.

As shown in step S12 of FIG. 1A, the manufacturing method of the electronic device may further include forming a semiconductor structure 14 on the sacrificial layer 12. FIG. 6 to FIG. 8 respectively illustrate the formation of the semiconductor structure 14 on the sacrificial layer 12 of FIG. 2 (or FIG. 5), FIG. 3 and FIG. 4, and the subsequent formation of the bonding layer 16 and the carrier 18 on the semiconductor structure 14. In some embodiments, the semiconductor structure 14 may include a diode structure, for example, may include a light-emitting diode structure. For example, the semiconductor structure 14 may include a first-type semiconductor layer, an active layer, and a second-type semiconductor layer formed sequentially on the sacrificial layer 12, but the disclosure is not limited thereto. In some embodiments, the first type semiconductor layer includes an N-type gallium nitride layer, the active layer may be a multiple quantum well layer and includes alternating stacks of multiple layers of indium gallium nitride and multiple layers of gallium nitride, and the second type semiconductor layer may include a P-type gallium nitride layer, but the disclosure is not limited thereto. In other embodiments, the first type semiconductor layer and the second type semiconductor layer may be P-type semiconductor layers and N-type semiconductor layers respectively, and the respective materials or ingredient proportion of the first type semiconductor layer, the active layer, and the second type semiconductor layer may be changed according to actual needs.

The bonding layer 16 may be used to bond the carrier 18 to the semiconductor structure 14. In some embodiments, the material of the bonding layer 16 may include solder, gold-indium alloy (Au/In), aluminum (Al), copper (Cu), tin-copper compounds (Cu₆Sn₅, Cu₃Sn, Cu₃Sn₄), tin-nickel compounds (Ni₆Sn₅, Ni₃Sn, Ni₃Sn₄), tin-copper-nickel compounds ((Cu₁₋ₓNiₓ)₆Sn₅, (Cu_{1-y}Ni_{y})₃Sn, (Cu_{1-z}Ni_{z})₃Sn₄) or other suitable conductive bonding materials, wherein 0.01≤x≤0.8, 0.01≤y≤0.8 and 0.1≤z≤0.8. The carrier 18 may include a silicon substrate, such as a silicon (100) substrate, but the disclosure is not limited thereto.

As shown in step S14 of FIG. 1A, the manufacturing method of the electronic device may further include separating the semiconductor structure 14 from the substrate 10. In some embodiments, as shown in FIG. 9 and FIG. 10, the method of separating the semiconductor structure 14 from the substrate 10 may include removing the peeling layer 120 by photoelectrical chemical etching (PEC etching). Specifically, the structure formed above may be immersed in the chemical solution CS and the structure formed above may be irradiated with a beam B to remove the peeling layer 120 and thereby separating the semiconductor structure 14 from the substrate 10. In some embodiments, as shown in FIG. 9 and FIG. 10, the material of buffer layer 122 may be different from the material of the peeling layer 120 such that the buffer layer 122 is retained after the PEC etching step. Alternatively, although not shown, the material of the buffer layer 122 may be the same as the material of the peeling layer 120 so that the buffer layer 122 is removed together after the PEC etching step.

The ingredients of the chemical solution CS and the wavelength and energy of the beam B may be determined according to the material of the film layer to be removed (such as the material of the peeling layer 120). For example, the ingredients of the chemical solution CS may include a combination of potassium hydroxide (KOH) and water, or a combination of nitric acid (HNO₃), hydrofluoric acid (HF), and acetic acid (CH₃COOH), but the disclosure is not limited thereto. In addition, the beam B may be a laser beam. When the wavelength of the beam B is 463 nm, the energy of the beam B at room temperature is, for example, about 180 kW/cm² to 230 kW/cm², and when the wavelength of the beam B is 475 nm, the energy of the beam B at room temperature is, for example, about 330 kW/cm² to 390 kW/cm², but the disclosure is not limited thereto.

In some embodiments, as shown in FIG. 11 and FIG. 12, the method of separating the semiconductor structure 14 from the substrate 10 may further include removing the peeling layer 120 with an infrared laser IRL. Specifically, the peeling layer 120 may be irradiated with the infrared laser IRL from a side where the substrate 10 is located. An infrared laser IRL that is able to penetrate the substrate 10 may be selected so that the infrared laser IRL penetrates the substrate 10 and focuses on the peeling layer 120. The energy generated by focusing the infrared laser IRL on the peeling layer 120 is used to burn the peeling layer 120, thereby separating the semiconductor structure 14 from the substrate 10.

In some embodiments, as shown in FIG. 13, FIG. 14, and FIG. 16A to FIG. 16C, the method of separating the semiconductor structure 14 FROM the substrate 10 may further include cutting the peeling layer 120 with a laser LS. Specifically, the laser LS may include a carbon dioxide laser or other types of lasers suitable for laser cutting, and the laser LS may cut off the peeling layer 120 along the cutting line CL as shown in FIG. 13 or FIG. 14. In some embodiments, as shown in FIG. 16A, when the laser LS is used to cut the peeling layer 120, the thickness T120 of the peeling layer 120 may be greater than 1 mm to improve the cutting margin or reduce the damage caused by the laser LS to adjacent film layers.

In some embodiments, as shown in FIG. 16A to FIG. 16C, in the process of cutting the peeling layer 120 with the laser LS, the laser LS, for example, forms the cutting marks CT on the opposite sides (e.g., the first side SW1 and the second side SW2) of the peeling layer 120. In the meantime, in the process of the cutting marks CT extending from the opposite sides (for example, the first side SW1 and the second side SW2) to the center C of the peeling layer 120, the energy of the laser LS may be high, low and high in order. For example, when the cutting marks CT are adjacent to the opposite sides (for example, the first side SW1 and the second side SW2) and at the center C, the energy of the laser LS may be greater than the energy of the laser LS when the cutting marks CT are located between the first side SW1 (or the second side SW2) and the center C. For clear identification, in FIG. 16A to FIG. 16C, thick arrows represent lasers with high energy, and thin arrows represent lasers with lower energy. When the cutting marks CT extend to the position between the first side SW1 (or the second side SW2) and the center C, by lowering the energy of the laser LS, the damage caused by the laser LS to the film layer adjacent to the peeling layer 120 may be reduced. In addition, when the cutting marks CT extend to the center C, by increasing the energy of the laser LS, the peeling layer 120 may be effectively cut off, thereby reducing the probability of the peeling layer 120 sticking to adjacent film layers or failing to be completely cut off.

In some embodiments, as shown in FIG. 17 and FIG. 18, cutting the peeling layer 120 with the laser LS (see FIG. 16A to FIG. 16C) may include aligning the cutting position with an alignment pattern AL, confirming the thickness (thickness of the layer to be cut) by using a ruler VK or a combination of the above. The alignment pattern AL may be, for example, holes or metal marks formed in the layer to be cut. For example, the alignment pattern AL may be holes or metal marks located on the surface of the sidewall of the peeling layer 120, but the disclosure is not limited thereto. Depending on different requirements, the alignment pattern AL may be formed in one or more of the above film layers.

In some embodiments, as shown in FIG. 15, the method of separating the semiconductor structure 14 from the substrate 10 may further include cutting the interface between the buffer layer 122 and the substrate 10 with the laser LS (refer to FIG. 16A to FIG. 16C). For example, in a structure in which the sacrificial layer 12 does not include the peeling layer 120, the interface between the buffer layer 122 and the substrate 10 may be cut by the laser LS (see FIG. 16A to FIG. 16C) to separate the semiconductor structure 14 from the substrate 10. When the laser LS is adopted to cut the interface between the buffer layer 122 and the substrate 10, the thickness T122 of the buffer layer 122 may be greater than 1 mm to improve the cutting margin or reduce the damaged caused by the laser LS to the adjacent film layer. Moreover, cutting the interface between the buffer layer 122 and the substrate 10 with the laser LS (see FIG. 16A to FIG. 16C) may also include aligning the cutting position with the alignment pattern AL (see FIG. 17), and confirming the thickness (e.g., thickness T122) by using the ruler VK (see FIG. 18) or a combination of the above. Furthermore, when cutting the buffer layer 122, the energy of the laser LS may also be adjusted according to the position of the cutting marks CT (refer to FIG. 16A to FIG. 16C and corresponding description).

In some embodiments, as shown in FIG. 19, the method of separating the semiconductor structure 14 from the substrate 10 may further include separating the semiconductor structure 14 from the peeling layer 120 using a thermal release tape TRT. For example, the thermal release tape TRT may be used to peel off the semiconductor structure 14 from the peeling layer 120 and then move the semiconductor structure 14 to another temporary substrate or carrier. In some embodiments, when the semiconductor structure 14 and the peeling layer 120 are separated with the thermal release tape TRT, the material of the buffer layer 122 includes, for example, C-plane alumina, and the material of the peeling layer 120 includes, for example, graphene, so that the semiconductor structure 14 may be easily separated from the peeling layer 120, but this disclosure is not limited thereto. Other materials for the buffer layer and the peeling layer are also intended to be included in this disclosure.

In some embodiments, as shown in step S16 of FIG. 1A, the manufacturing method of the electronic device may further include removing the sacrificial layer 12 or impurities remaining on the substrate 10 after separating the semiconductor structure 14 from the substrate 10 and before detecting defects on the substrate 10. For example, as shown in FIG. 20, the substrate 10 may be cleaned by chemical etching, wherein the etchant ET includes, for example, acetic acid (CH₃COOH), hydrochloric acid (HCL), nitric acid (HNO₃), phosphoric acid (H₃PO₄), sulfuric acid (H₂SO₄), potassium hydroxide (KOH), potassium hydroxide plus water, potassium hydroxide plus ethylene glycol, sodium hydroxide (NaOH) plus water, sodium hydroxide plus ethylene glycol or other suitable etchants.

In some embodiments, as shown in step S18 of FIG. 1A, the manufacturing method of the electronic device may also include, while detecting the defects on the substrate 10, detecting cracks on the substrate 10 and determining whether the substrate 10 may be cut to a size greater than or equal to a threshold size in the presence of defects or cracks on the substrate. For example, as shown in FIG. 21, an automated optical inspection (AOI) system S may be used to detect whether the substrate 10 has defects DF (refer to FIG. 22) and/or cracks CK (refer to FIG. 23). If defects DF and/or cracks CK are detected on the substrate 10, the defects DF and/or cracks CK are removed by reducing the size of the substrate 10. If it is determined that the substrate 10 has defects DF or cracks CK and may be cut to a size greater than or equal to the threshold size, the size of the substrate 10 may be reduced, as shown in step S20 of FIG. 1A and FIG. 22 and FIG. 23. If it is determined that the substrate 10 cannot be cut to a size greater than or equal to the threshold size in the presence of defects DF or cracks CK on the substrate, the substrate 10 may be scrapped, as shown in step S22 of FIG. 1A.

Taking the semiconductor structure 14 as a light-emitting diode structure as an example, currently the substrates for producing LED chips are mainly four inches, so the threshold size may be set as four inches. If it is determined that the size of the substrate 10 must be reduced to four inches, six inches, or eight inches to remove defects DF and/or cracks CK, step S20 of FIG. 1A may be performed subsequently. On the other hand, if it is determined that the size of the substrate 10 must be reduced to less than four inches in order to remove the defects DF and/or the cracks CK, then step S22 of FIG. 1A may be performed subsequently.

In some embodiments, the scrapped substrate 10 may be broken into particles to be used as heat dissipation materials in related processes. In other embodiments, the scrapped substrate 10 may be subjected to a semiconductor recycling process. In yet other embodiments, the scrapped substrate 10 may be used for educational training or experimentation.

In some embodiments, as shown in step S24 of FIG. 1A, the manufacturing method of the electronic device may further include performing CMP on the substrate 10 after detecting defects on the substrate 10 and before classifying the substrate 10. For example, if it is determined that the substrate 10 has no defects DF and cracks CK, CMP may be continued. As shown in FIG. 24, the slurry SL may be used as the abrasive, and the substrate 10 is pressed down on the polishing pad PP through the polishing head PH to perform CMP. During the CMP process, the polishing head PH and the polishing pad PP may be rotated to planarize the surface of the substrate 10.

In some embodiments, as shown in step S26 of FIG. 1A, the manufacturing method of the electronic device may further include detecting the thickness T10 and surface roughness of the substrate 10 undergone CMP. As shown in FIG. 25 and FIG. 26, a non-contact thickness detection method may be used to detect the thickness T10 and surface roughness (e.g., arithmetic average roughness Ra, AA) of the substrate 10. For example, as shown in FIG. 25, the substrate 10 may be placed on the stage G and the light is split into different focal lengths as a function of wavelength by the optical probe P. According to the wavelength of the reflected light received by the light receiver R, the distance is measured, thereby calculating the thickness T10 and surface roughness of the substrate 10. In some embodiments, the thickness T10 and surface roughness of the substrate 10 may be measured in different areas.

In some embodiments, if the thickness T10 and the surface roughness conform to a specification, the substrate 10 undergone CMP is chemically cleaned, as shown in step S28 of FIG. 1B, and if any one of the thickness T10 and the surface roughness does not conform to the specification, CMP may be performed again, for example, step S24 in FIG. 1A is performed again. In some embodiments, after determining that any one of the thickness T10 and the surface roughness does not conform to the specification (for example, when Ra>10 nm) and before performing CMP again, the number of times of the CMP performed on the substrate 10 may be first confirmed. If the number of times the substrate 10 undergoes CMP has not reached the threshold, CMP may be performed again, for example, step S24 in FIG. 1A is performed again. On the other hand, if the number of times the substrate 10 has been subjected to CMP reaches the threshold, the substrate 10 may be scrapped, for example, step S22 in FIG. 1A is performed.

In some embodiments, as shown in FIG. 27, performing chemical cleaning on the substrate 10 subjected to CMP may include immersing the substrate 10 in a chemical solution CS′ to remove impurities or contamination remaining on the substrate 10. In some embodiments, the chemical cleaning described in step S28 may also be referred to as RCA cleaning.

In some embodiments, as shown in step S30 of FIG. 1B, the manufacturing method of the electronic device may further include determining the number and size of particles on the substrate 10 before classifying the substrate 10. For example, the number and size of particles on the substrate 10 may be determined by the automated optical inspection (AOI) system S as shown in FIG. 21. If the number and size of the particles on the substrate 10 conform to the specification, the substrate 10 is classified according to the thickness T10 of the substrate 10, as shown in step S32 of FIG. 1B, and if any of the number and size of the particles on the substrate 10 does not conform to the specification, the substrate 10 may be scrapped, for example, step S22 in FIG. 1B is performed. In some embodiments, if the number of particles on the substrate 10 is greater than five and/or the size of the particles is greater than 0.5 nm*0.5 nm, the substrate 10 may be scrapped, for example, step S22 of FIG. 1B is performed.

In some embodiments, as shown in FIG. 28, classifying the substrate 10 may include storing the substrate 10 in different storage cabinets for use of next time according to the thickness T10 of the substrate 10, and/or the substrate 10 repeatedly used for different number of times may be stored in different storage cabinets depending on the number of times of repetitive use of the substrate 10. For example, the substrate 10 with a thickness T10 greater than or equal to 800 nm and less than or equal to 2000 nm may be stored in the storage cabinet ST1, the substrate 10 with a thickness T10 greater than or equal to 300 nm and less than 800 nm may be stored in the storage cabinet ST2, and the substrate 10 with a thickness T10 greater than or equal to 50 nm and less than 300 nm may be stored in the storage cabinet ST3, but the disclosure is not limited thereto. In some embodiments, the humidity in the storage cabinet (such as storage cabinet ST1, storage cabinet ST2 and/or storage cabinet ST3) may be greater than 7% of the ambient humidity and less than 30% of the ambient humidity, but the disclosure is not limited thereto.

In some embodiments, in consideration of the convenience of warehousing management, the service life of the substrate and other factors, when the substrate 10 stored in the storage cabinet (such as storage cabinet ST1, storage cabinet ST2 and/or storage cabinet ST3) is to be used repetitively, a substrate 10 with a smaller thickness T10 (such as the substrate 10 in the storage cabinet ST3) may be preferably used for growing the aforementioned semiconductor structure 14, but the disclosure is not limited thereto.

Please refer to FIG. 29A and FIG. 29B. The main difference between the manufacturing method of the electronic device shown in FIG. 29A and FIG. 29B and the manufacturing method of the electronic device shown in FIG. 1A and FIG. 1B is that the manufacturing method of the electronic device shown in FIG. 29A omits the step S16 of FIG. 1A, and there are differences between steps S24′, S26′, S28′ and S32′ shown in FIG. 29A and FIG. 29B and steps S24, S26, S28 and S32 shown in FIG. 1A and FIG. 1B.

Specifically, the manufacturing method of the electronic device shown in FIG. 29A and FIG. 29B omits the step of removing the sacrificial layer 12 remaining on the substrate 10 (step S16 in FIG. 1A). In this way, it is possible to omit the step of forming the sacrificial layer 12 or saving the number of steps of forming the sacrificial layer 12 when the substrate 10 is used repetitively. For example, in the steps of separating the semiconductor structure 14 from the substrate 10 as shown in FIG. 10, FIG. 12, FIG. 14 and/or FIG. 19, at least the buffer layer 122 in the sacrificial layer 12 remains on the substrate 10. Therefore, in the case of omitting the step of removing the sacrificial layer 12 remaining on the substrate 10, at least the buffer layer 122 in the sacrificial layer 12 may be retained on the substrate 10 and stored together in a storage cabinet (such as storage cabinet ST1, storage cabinet ST2 and/or storage cabinet ST3 shown in FIG. 33). In this way, when the substrate 10 in the storage cabinet is selected for reuse, the formation of the sacrificial layer 12 may be omitted or at least the formation of the buffer layer 122 may be omitted to save the number of steps of forming the sacrificial layer 12.

Under the structure of omitting the step of removing the sacrificial layer 12 remaining on the substrate 10, in step S24′ in FIG. 29A, after detecting defects on the substrate 10 (such as step S18) and before classifying the substrate 10 (such as step S32), CMP is performed on the sacrificial layer 12 remaining on the substrate 10. As shown in FIG. 30, if the sacrificial layer 12 remaining on the substrate 10 includes the buffer layer 122, CMP is performed on the buffer layer 122.

Under the structure of omitting the step of removing the sacrificial layer 12 remaining on the substrate 10, in step S26′ in FIG. 29A, the thickness and surface roughness of the sacrificial layer 12 undergone CMP are detected. As shown in FIG. 31 and FIG. 32, if the sacrificial layer 12 remaining on the substrate 10 includes the buffer layer 122, the thickness T122 and the surface roughness of the buffer layer 122 undergone CMP are detected.

Under the structure of omitting the step of removing the sacrificial layer 12 remaining on the substrate 10, in step S28′ in FIG. 29B, if the thickness and surface roughness of the sacrificial layer 12 conform to the specification, the sacrificial layer 12 undergone CMP is chemically cleaned. In some embodiments, substrate 10 may be chemically cleaned at the same time. Specifically, the substrate 10 and the sacrificial layer 12 thereon may be immersed in the chemical solution CS′ as shown in FIG. 27.

Under the structure of omitting the step of removing the sacrificial layer 12 remaining on the substrate 10, in step S32′ in FIG. 29B, if the number and size of particles on the substrate 10 conform to the specification, the substrate 10 may be classified according to the thickness T10 of the substrate 10, the surface roughness of the sacrificial layer 12 remaining on the substrate 10, or a combination of the above. Taking FIG. 33 as an example, classifying the substrate 10 may include storing the substrate 10 in different storage cabinets for use of next time according to the thickness T10 of the substrate 10, the surface roughness (such as the surface roughness of the buffer layer 122) of the sacrificial layer 12 remaining on the substrate 10, or a combination of the above. Furthermore, as mentioned above, it may be determined whether the substrate 10 is placed in the storage cabinet ST1, the storage cabinet ST2, or the storage cabinet ST3 according to the thickness T10 of the substrate 10. In some embodiments, as shown in FIG. 33, each storage cabinet may be further divided into layers based on the surface roughness (e.g., the surface roughness of the buffer layer 122) of the sacrificial layer 12. For example, the storage cabinet ST1, the storage cabinet ST2, and the storage cabinet ST3 each includes a first layer L1, a second layer L2 and a third layer L3, wherein the first layer L1 is configured to place the sacrificial layer 12 with a surface roughness (such as the surface roughness of the buffer layer 122) less than 5 nm and the substrate 10 located thereunder, the second layer L2 is configured to place the sacrificial layer 12 with a surface roughness (such as the surface roughness of the buffer layer 122) greater than or equal to 5 nm and less than 10 nm and the substrate 10 located thereunder, and the third layer L3 is configured to place the sacrificial layer 12 with a surface roughness (such as the surface roughness of the buffer layer 122) greater than or equal to 10 nm and the substrate 10 located thereunder. In other words, the third layer L3 in the storage cabinet ST2 is configured to place the sacrificial layer 12 with a surface roughness (such as the surface roughness of the buffer layer 122) greater than or equal to 10 nm and the substrate 10 located thereunder with a thickness T10 greater than or equal to 300 nm and less than 800 nm.

In some embodiments, in consideration of the convenience of warehousing management, the service life of the substrate and other factors, when the substrate 10 stored in the storage cabinet (such as storage cabinet ST1, storage cabinet ST2 and/or storage cabinet ST3) is to be used repetitively, a substrate 10 with a smaller thickness T10 (such as the substrate 10 in the third layer L3 of the storage cabinet ST3) and a sacrificial layer 12 with a larger surface roughness may be preferably used for growing the aforementioned semiconductor structure 14, but the disclosure is not limited thereto.

In some embodiments, as shown in FIG. 34, the manufacturing method of the electronic device may include: forming a semiconductor structure on the recycled substrate (step S40); separating the semiconductor structure from the recycled substrate (step S42); performing a product inspection on the semiconductor structure (step S44); and performing a recycling inspection on the recycled substrate (step S46). For example, in step S40, the recycled substrate may be taken out from the aforementioned storage cabinet (see FIG. 28 or FIG. 33). In step S42, if there is a sacrificial layer 12 on the recycled substrate (see FIG. 33), step S10 in FIG. 1A or FIG. 29A may be selectively omitted, and step S12 in FIG. 1A or FIG. 29A is performed. In contrast, if there is no sacrificial layer 12 on the recycled substrate (see FIG. 28), steps S10 and S12 in FIG. 1A or 29A may be performed sequentially. In step S44, performing the product inspection on the semiconductor structure may include performing electrical testing or lighting testing on the semiconductor structure (such as the aforementioned semiconductor structure 14) to confirm that the semiconductor structure is able to operate normally. In step S46, performing recycling inspection on the recycled substrate may include subsequently performing step S18 in FIG. 1A or FIG. 29A and following steps. Taking FIG. 1A as an example, step S20, step S22 or step S24 may follow after step S18 is performed. Step S24 may follow after step S20 is performed. Step S26 may follow after step S24 is performed. Step S24 or step S28 may follow after step S26 is performed. Step S30 may follow after step S28 is performed. Step S22 or step S32 may follow after step S30 is performed. FIG. 29A may be understood by analogy and related details will not be repeated here.

To sum up, in the embodiments of the present disclosure, by classifying the substrate separated from the semiconductor structure for subsequent reuse, it is helpful to reduce the manufacturing cost for electronic devices.

Finally, it should be noted that the above embodiments are only used to illustrate the technical solutions of the disclosure and are not intended to limit it. Although the disclosure has been described in detail with reference to the above embodiments, persons of ordinary skill in the art should understand that they may still modify the technical solutions described in the above embodiments, or replace some or all of the technical features therein with equivalents, and that modifications or replacements of corresponding technical solutions do not substantially deviate from the scope of the technical solutions of the embodiments of the disclosure.

Although the embodiments of the disclosure and the advantages of the embodiments have been disclosed above, it should be understood that any person of ordinary skill in the art may make changes, substitutions, and modifications without departing from the spirit and scope of the disclosure. Moreover, the features of the various embodiments may be mixed and replaced with each other at discretion to form other new embodiments. In addition, the protection scope of the disclosure is not limited to the processes, machines, manufacture, compositions of matter, devices, methods, and steps in the specific embodiments described in the specification. Any person of ordinary skill in the art may understand the present or future developed processes, machines, manufacture, compositions of matter, devices, methods, and steps from the disclosure, which may be used based on the disclosure as long as they can perform substantially the same functions or achieve substantially the same results in the embodiments described herein. Therefore, the protection scope of the disclosure includes the above-mentioned processes, machines, manufacture, compositions of matter, devices, methods, and steps. In addition, each claim constitutes a separate embodiment, and the protection scope of the disclosure also includes combinations of each claim and the embodiment. The scope of protection of the disclosure shall be defined by the appended claims.

What is claimed is:

1. A manufacturing method of an electronic device, comprising:
forming a sacrificial layer on a substrate;
forming a semiconductor structure on the sacrificial layer;
separating the semiconductor structure from the substrate;
detecting defects on the substrate; and
classifying the substrate.

2. The manufacturing method of the electronic device according to claim 1, wherein the substrate is a silicon substrate.

3. The manufacturing method of the electronic device according to claim 1, wherein the substrate is a silicon substrate, and the manufacturing method of the electronic device further comprises:
cutting the silicon substrate into a thin substrate after forming the sacrificial layer on the silicon substrate.

4. The manufacturing method of the electronic device according to claim 1, wherein the sacrificial layer comprises a buffer layer, a peeling layer or a combination of the above.

5. The manufacturing method of the electronic device according to claim 4, wherein a material of the buffer layer comprises N-type gallium nitride, graphene, aluminum nitride, silicon dioxide or aluminum oxide.

6. The manufacturing method of the electronic device according to claim 4, wherein a material of the peeling layer comprises aluminum gallium nitride, graphene, a combination of the graphene and the aluminum oxide, indium gallium nitride, aluminum indium gallium nitride, aluminum indium gallium arsenide or silicon carbide.

7. The manufacturing method of the electronic device according to claim 4, wherein the method for separating the semiconductor structure from the substrate comprises:
removing the peeling layer by photoelectrical chemical etching;
removing the peeling layer with an infrared laser;
cutting the peeling layer with a laser;
cutting an interface between the buffer layer and the substrate with the laser; or
separating the semiconductor structure from the peeling layer using a thermal release tape.

8. The manufacturing method of the electronic device according to claim 7, wherein when the peeling layer is cut with the laser, or the interface between the buffer layer and the substrate is cut with the laser, a thickness of the buffer layer or the peeling layer is greater than 1 mm.

9. The manufacturing method of the electronic device according to claim 7, wherein cutting the peeling layer with the laser or cutting the interface between the buffer layer and the substrate with the laser comprises aligning a cutting position with an alignment pattern, and confirming a thickness by using a ruler or a combination of the above.

10. The manufacturing method of the electronic device according to claim 7, wherein in the process of cutting the peeling layer with the laser, the laser forms cutting marks on opposite sides of the peeling layer, and in a process of the cutting marks extending from the opposite sides to a center of the peeling layer, an energy of the laser is high, low and high in order.

11. The manufacturing method of the electronic device according to claim 7, wherein when the semiconductor structure and the peeling layer are separated with the thermal release tape, a material of the buffer layer comprises C-plane alumina, and a material of the peeling layer comprises graphene.

12. The manufacturing method of the electronic device according to claim 1, further comprising:
removing the sacrificial layer or impurities remaining on the substrate after separating the semiconductor structure from the substrate and before detecting the defects on the substrate.

13. The manufacturing method of the electronic device according to claim 1, further comprising:
while detecting the defects on the substrate, detecting cracks on the substrate and determining whether the substrate is able to be cut to a size greater than or equal to a threshold size in the presence of the defects or the cracks on the substrate.

14. The manufacturing method of the electronic device according to claim 13, wherein if it is determined that the substrate has the defects or the cracks and is able to be cut to the size greater than or equal to the threshold size, the size of the substrate is reduced, and if it is determined that the substrate is not able to be cut to the size greater than or equal to the threshold size in the presence of the defects or the cracks on the substrate, the substrate is scrapped.

15. The manufacturing method of the electronic device according to claim 1, further comprising:
performing chemical-mechanical polishing (CMP) on the substrate or the sacrificial layer remaining on the substrate after detecting the defects on the substrate and before classifying the substrate; and
detecting a thickness and a surface roughness of the substrate or the sacrificial layer undergone the CMP.

16. The manufacturing method of the electronic device according to claim 15, wherein if the thickness and the surface roughness conform to a specification, the substrate or the sacrificial layer undergone the CMP is chemically cleaned, and if any one of the thickness and the surface roughness does not conform to the specification, the CMP is performed again.

17. The manufacturing method of the electronic device according to claim 16, wherein if the number of times the substrate has been subjected to the CMP reaches a threshold, the substrate is scrapped.

18. The manufacturing method of the electronic device according to claim 1, further comprising:
determining a number and a size of particles on the substrate before classifying the substrate.

19. The manufacturing method of the electronic device according to claim 18, wherein if the number and the size of the particles on the substrate conform to a specification, the substrate is classified according to a thickness of the substrate, a surface roughness of the sacrificial layer remaining on the substrate or a combination of the above, and if any of the number and the size of the particles on the substrate does not conform to the specification, the substrate is scrapped.

20. The manufacturing method of the electronic device according to claim 1, wherein classifying the substrate comprises storing the substrate in different storage cabinets for use of next time according to a thickness of the substrate, a surface roughness of the sacrificial layer remaining on the substrate or a combination of the above.
